(19) United States
(12) Patent Application Publication
(10) Pub. No.: US 2025/0118550 A1
(43) Pub. Date: Apr. 10, 2025

(54) SUBSTRATE-PROCESSING METHOD AND SUBSTRATE-PROCESSING APPARATUS

(71) Applicant: Tokyo Electron Limited, Tokyo (JP)

(72) Inventor: Munehito KAGAYA, Tokyo (JP)

(21) Appl. No.: 18/982,168

(22) Filed: Dec. 16, 2024

Related U.S. Application Data
(63) Continuation of application No. PCT/JP2023/025767, filed on Jul. 12, 2023.

(30) Foreign Application Priority Data
Jul. 19, 2022 (JP) 2022-115032

(51) Int. Cl. H01L 21/02; C23C 16/455; C23C 16/52

(52) U.S. Cl. CPC H01L 21/0228; C23C 16/45523; C23C 16/52; H01L 21/0217; H01L 21/02208; H01L 21/02274

(57) ABSTRACT

A substrate-processing method is provided for filling a recess formed in a surface of a substrate with a silicon nitride film. The substrate-processing method includes: a) repeating a cycle that includes i) supplying a silicon precursor gas to form an adsorption layer on the substrate, ii) supplying a nitrogen-containing gas to cause nitriding of the adsorption layer, and iii) supplying a helium-containing gas and generating helium plasma in a processing chamber to expose the substrate to the helium plasma, thereby forming an adsorption inhibition region on the substrate; and b) changing conditions for generating the helium plasma according to an increase in a number of the cycles repeated.

### CROSS-REFERENCE TO RELATED APPLICATIONS

The present application is a continuation application of International Application No. PCT/JP2023/025767 filed on Jul. 12, 2023, which is based on and claims priority to Japanese Patent Application No. 2022-115032 filed on Jul. 19, 2022, the contents of which are incorporated herein by reference.

### BACKGROUND

### 1. Field of the Invention

The present disclosure relates to substrate-processing methods and substrate-processing apparatuses.

### 2. Description of the Related Art

A production method of a semiconductor device is disclosed in Japanese Patent No. 2017-69407. In the disclosed production method, a cycle including a step of supplying a halogen-based raw material gas to a substrate having a surface in which a trench is formed, a step of supplying a reaction gas to the substrate, and a step of supplying a reaction inhibition gas to the substrate under first processing conditions is repeated a set number of times in a time-sharing system; and a cycle including a step of supplying the halogen-based raw material gas to the substrate, a step of supplying the reaction gas to the substrate, and a step of supplying the reaction inhibition gas to the substrate under second processing conditions that are different from the first processing conditions is repeated a set number of times in a time-sharing system, thereby forming a film in the trench.

### SUMMARY

According to one aspect of the present disclosure, a substrate-processing method is a substrate-processing method of filling a recess formed in a surface of a substrate with a silicon nitride film. The substrate-processing method includes: a) repeating a cycle that includes i) supplying a silicon precursor gas to form an adsorption layer on the substrate, ii) supplying a nitrogen-containing gas to cause nitriding of the adsorption layer, and iii) supplying a helium-containing gas and generating helium plasma in a processing chamber to expose the substrate to the helium plasma, thereby forming an adsorption inhibition region on the substrate; and b) changing conditions for generating the helium plasma according to an increase in a number of the cycles repeated.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic view illustrating a configuration example of a substrate-processing apparatus;

FIG. 2 is a timing diagram illustrating one example of a silicon nitride (SiN) film formation process according to the first example;

FIG. 3 is a timing diagram illustrating one example of an SiN film formation process according to the second example;

FIG. 4 is one example of a graph illustrating a film formation speed;

FIG. 5 is one example of a graph illustrating a relation between a plasma exposure time and amino (NHx) groups in the film;

FIG. 6A is one example of a schematic cross-sectional view illustrating a process of filling a recess with an SiN film;

FIG. 6B is one example of a schematic cross-sectional view illustrating the process of filling the recess with the SiN film; and

FIG. 6C is one example of a schematic cross-sectional view illustrating the process of filling the recess with the SiN film.

### DETAILED DESCRIPTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

### [Substrate-Processing Apparatus]

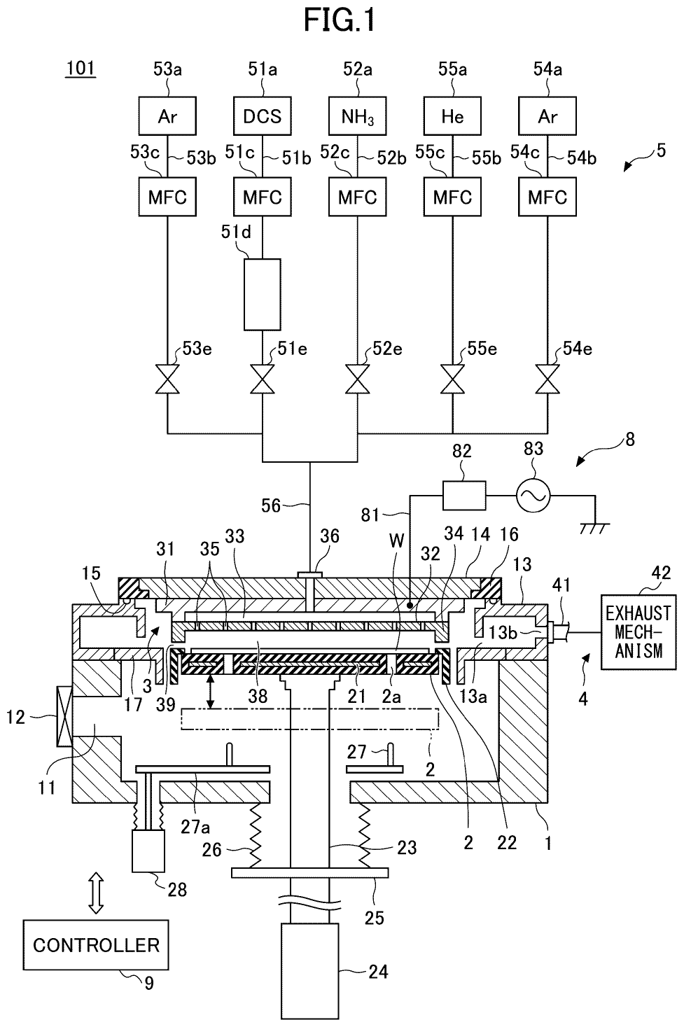

The substrate-processing apparatus 101 according to the present embodiment will be described with reference to FIG. 1. FIG. 1 is a schematic view illustrating a configuration example of the substrate-processing apparatus 101. The substrate-processing apparatus 101 is configured to form an SiN film (silicon nitride film) on a substrate W, such as a semiconductor wafer or the like, in a processing chamber in a vacuumed state by plasma enhanced atomic layer deposition (PE-ALD) or thermal ALD (Th-ALD).

As illustrated in FIG. 1, the substrate-processing apparatus 101 includes a processing chamber 1, a stage 2, a showerhead 3, an exhaust 4, a gas supply mechanism 5, a radio frequency (RF)-power supply 8, and a controller 9.

The processing chamber 1 is formed of a metal, such as aluminum or the like, and has substantially a cylindrical shape. The processing chamber 1 houses a substrate W. A loading port 11 through which the substrate W is transported in and out is formed in a side wall of the processing chamber 1. The loading port 11 is opened and closed by a gate valve 12. An annular exhaust duct 13 having a rectangular cross-sectional shape is disposed above a main body of the processing chamber 1. A slit 13a is formed along an inner circumferential surface of the exhaust duct 13. An exhaust port 13b is formed in an outer wall of the exhaust duct 13. A ceiling wall 14 is disposed on an upper surface of the exhaust duct 13 to cover an upper opening of the processing chamber 1 via an insulating member 16. A space between the exhaust duct 13 and the insulating member 16 is airtightly sealed by a seal ring 15. A partition member 17 partitions the interior of the processing chamber 1 into an upper side and a lower side when the stage 2 (and a cover member 22) is lifted to a below-described processing position.

The stage 2 horizontally supports the substrate W in the processing chamber 1. The stage 2 is formed in a disc shape having a size corresponding to the substrate W, and is supported by a support member 23. The stage 2 is formed of a ceramic material, such as aluminum nitride (AlN) or the like, or a metal material, such as aluminum, a nickel alloy, or the like, and a heater 21 for heating the substrate W is embedded in the stage 2. A heater power supply (not illustrated) supplies electricity to the heater 21 to generate heat. The temperature of the substrate W is regulated at a set temperature by controlling an output of the heater 21 according to a temperature signal of a thermocouple (not illustrated) disposed in the vicinity of an upper surface of the stage 2. A cover member 22 formed of a ceramic, such as alumina or the like, is disposed above the stage 2 to cover an outer peripheral region of the upper surface of the stage 2, and a side surface of the stage 2.

A support member 23 is disposed on a bottom surface of the stage 2, and supports the stage 2. The support member 23 extends from a center of the bottom surface of the stage 2 to the bottom of the processing chamber 1 through a hole formed in a bottom wall of the processing chamber 1, and a lower end of the support member 23 is coupled to a lifting mechanism 24. The stage 2 is lifted up and lowered down, by the lifting mechanism 24, between the processing position and the loading position illustrated in FIG. 1. The loading position is indicated with a double-dashed chain line, and is a position where the substrate W can be transported in and out. A flange 25 is attached to the support member 23 below the processing chamber 1. A bellows 26 is disposed between the bottom surface of the processing chamber 1 and the flange 25. The bellows 26 partitions the inner atmosphere of the processing chamber 1 off from the outside air, and expands and contracts according to the lifting and lowering movements of the stage 2.

In the vicinity of the bottom surface of the processing chamber 1, three (only two are illustrated) wafer support pins 27 are disposed to be projected upward from a lifting plate 27a. The wafer support pins 27 are lifted up and lowered down with the lifting plate 27a by a lifting mechanism 28 disposed below the processing chamber 1. The wafer support pins 27 are inserted through holes 2a formed in the stage 2 in the loading position to be projected from and pulled down from the upper surface of the stage 2. By lifting and lowering the wafer support pins 27, the substrate W is transported between a transfer mechanism (not illustrated) and the stage 2.

The showerhead 3 is configured to supply a processing gas into the processing chamber 1 in the form of a shower. The showerhead 3 is formed of a metal, disposed to face the stage 2, and has substantially the same diameter as a diameter of the stage 2. The showerhead 3 includes a main body 31 and a shower plate 32. The main body 31 is fixed onto the ceiling wall 14 of the processing chamber 1. The shower plate 32 is connected to the bottom of the main body 31. A gas diffusion space 33 is created between the main body 31 and the shower plate 32. A gas inlet hole 36 is provided to the gas diffusion space 33, where the gas inlet hole 36 penetrates through the ceiling wall 14 of the processing chamber 1 and a center of the main body 31. An annular projection 34 projecting downward is formed on the peripheral edge of the shower plate 32. Gas discharge holes 35 are formed in a flat portion located on an inner side of the annular projection 34. In a state where the stage 2 is in the processing position, a processing space 38 is created between the stage 2 and the shower plate 32, and an annular gap 39 is formed by bringing the upper surface of the cover member 22 close to the annular projection 34.

The exhaust 4 exhausts the inner atmosphere of the processing chamber 1. The exhaust 4 includes an exhaust pipe 41 connected to an exhaust port 13b, and an exhaust mechanism 42 connected to the exhaust pipe 41. The exhaust mechanism 42 includes a vacuum pump, a pressure control valve, and the like. During processing, a gas inside the processing chamber 1 passes through the slit 13a to reach the exhaust duct 13, and the gas is exhausted from the exhaust duct 13 by the exhaust mechanism 42 through the exhaust pipe 41.

The gas supply mechanism 5 is configured to supply a processing gas into the processing chamber 1. The gas supply mechanism 5 includes a silicon precursor gas source 51a, a reaction gas source 52a, an argon (Ar) gas source 53a, an Ar gas source 54a, and an adsorption inhibition gas source 55a.

The silicon precursor gas source 51a supplies a silicon precursor gas (silicon-containing precursor gas) to the processing chamber 1 through a gas supply line 51b. As the silicon precursor, halogenated silane, aminosilane, silyl amine, any combination of the foregoing, or the like can be used. In FIG. 1 and the description below, the description is given with assumption that a dichlorosilane (DCS) gas is used as the silicon precursor gas. A flow-rate regulator 51c, a reservoir tank 51d, and a valve 51e are provided to the gas supply line 51b in this order from the upstream side. The downstream side of the gas supply line 51b relative to the valve 51e is coupled to a gas inlet hole 36 via a gas supply line 56. A silicon precursor gas supplied from the silicon precursor gas source 51a is temporarily retained in the reservoir tank 51d before being supplied to the processing chamber 1 and is pressurized at a set pressure in the reservoir tank 51d, followed by being supplied to the processing chamber 1. The supply of the silicon precursor gas from the reservoir tank 51d to the processing chamber 1 and the stop of supply are performed by opening and closing the valve 51e. Since the silicon precursor gas is temporarily retained in the reservoir tank 51d as described above, the silicon precursor gas can be stably supplied to the processing chamber 1 at a relatively high flow rate.

The reaction gas source 52a supplies a reaction gas to the processing chamber 1 through a gas supply line 52b. The reaction gas is a reaction gas that thermally reacts with the silicon precursor, or a reaction gas whose plasma active species reacts with the silicon precursor. A nitrogen-containing gas can be used as the reaction gas. As the nitrogen-containing gas, at least one selected from the group consisting of an ammonia (NH₃) gas, a diazene (N₂H₂) gas, a nitrogen (N₂) gas, a gas mixture of an No gas and a hydrogen (H₂) gas, any combination of the preceding gasses, and a plasma active species of any of the preceding gasses can be used. The nitrogen-containing gas is a gas that reacts with the silicon precursor (by a thermal reaction or a reaction of plasma active species), thereby nitriding the silicon precursor. As the nitrogen-containing gas that thermally reacts with the silicon precursor, at least one selected from the group consisting of an NH₃ gas, an N₂H₂ gas, a combination of the preceding gasses, and the like can be used. As the nitrogen-containing gas whose plasma active species reacts with the silicon precursor, at least one selected from the group consisting of an NH₃ gas, an N₂ gas, a H₂ gas, any combination of the preceding gasses, and the like can be used. In FIG. 1 and the description below, the description is given with assumption that an NH₃ gas is used as the reaction gas (nitrogen-containing gas). A flow-rate regulator 52c and a valve 52e are provided to the gas supply line 52b in this order from the upstream side. The downstream side of the gas supply line 52b relative to the valve 52e is coupled to the gas inlet hole 36 via the gas supply line 56. The reaction gas supplied from the reaction gas source 52a is supplied to the processing chamber 1. The supply of the reaction gas to the processing chamber 1 and the stop of supply are performed by opening and closing the valve 52e.

The Ar gas source 53a supplies an Ar gas serving as an inert gas to the processing chamber 1 through a gas supply line 53b. A flow-rate regulator 53c and a valve 53e are provided to the gas supply line 53b in this order from the upstream side. The downstream side of the gas supply line 53b relative to the valve 53e is coupled to the gas supply line 51b. The Ar gas supplied from the Ar gas source 53a is supplied to the processing chamber 1. The supply of the Ar gas to the processing chamber 1 and the stop of supply are performed by opening and closing the valve 53e.

The Ar gas source 54a supplies an Ar gas serving as an inert gas to the processing chamber 1 through a gas supply line 54b. A flow-rate regulator 54c and a valve 54e are provided to the gas supply line 54b from the upstream side. The downstream side of the gas supply line 54b relative to the valve 54e is coupled to the gas supply line 52b. The Ar gas supplied from the Ar gas source 54a is supplied to the processing chamber 1. The supply of the Ar gas to the processing chamber 1 and the stop of supply are performed by opening and closing the valve 54e.

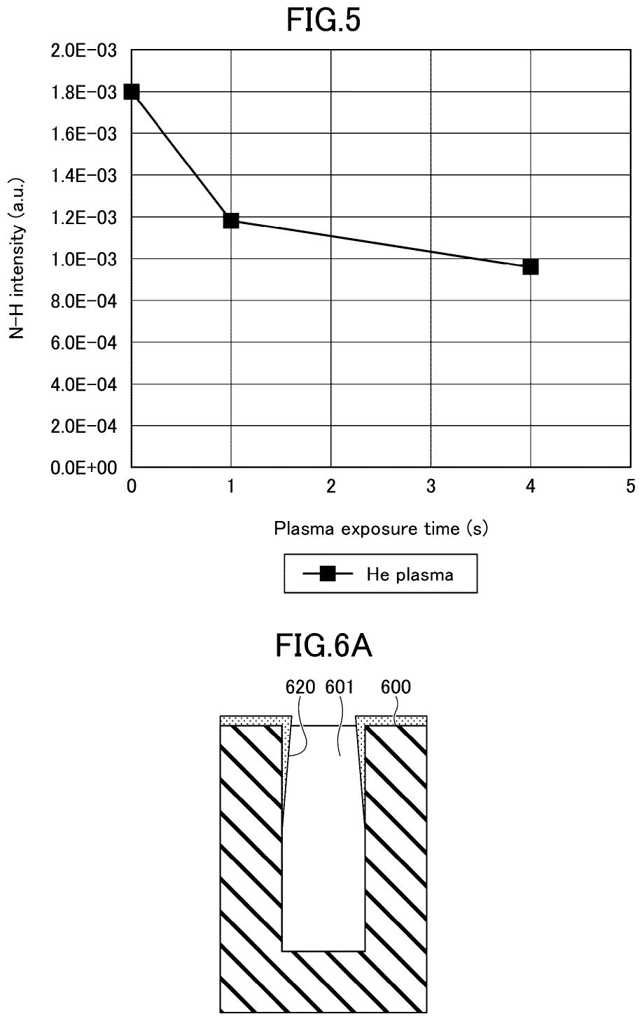

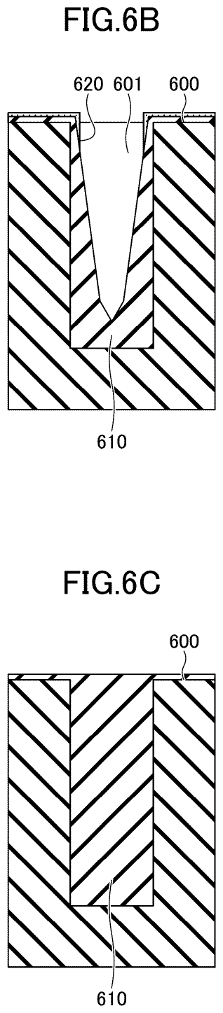

The adsorption inhibition gas source 55a supplies a He gas serving as an adsorption inhibition gas (first adsorption inhibition gas) to the processing chamber 1 through a gas supply line 55b. The adsorption inhibition gas (first adsorption inhibition gas) forms an adsorption inhibition region 620 (see below-described FIGS. 6A and 6B) in the vicinity of an opening of a recess 601 formed in the substrate W. As the adsorption inhibition gas, a He-containing gas can be used. In FIG. 1 and the description below, the description is given with assumption that a He gas (helium-containing gas) is used as the adsorption inhibition gas. A flow-rate regulator 55c and a valve 55e are provided to the gas supply line 55b from the upstream side. The downstream side of the gas supply line 55b relative to the valve 55e is coupled to the gas supply line 52b. The He gas supplied from the adsorption inhibition gas source 55a is supplied to the processing chamber 1. The supply of the He gas to the processing chamber 1 and the stop of supply are performed by opening and closing the valve 55e.

The substrate-processing apparatus 101 is a capacitively coupled plasma device, in which the stage 2 serves as a lower electrode, and the showerhead 3 serves as an upper electrode. The stage 2 serving as the lower electrode may be grounded via a capacitor (not illustrated).

The RF-power supply 8 supplies high-frequency power (may be referred to as “RF power” hereinafter) to the showerhead 3 serving as an upper electrode. The RF-power supply 8 includes a power supply line 81, an impedance matching device 82, and an RF-power source 83. The RF-power source 83 is a power source that generates RF power. The RF-power frequencies are suitable for generation of plasma. The frequencies of the RF power are, for example, in a range of 450 KHz to 100 MHz. The RF-power source 83 is coupled to the main body 31 of the showerhead via the impedance matching device 82 and the power supply line 81. The impedance matching device 82 includes a circuit for matching lead impedance (upper electrode) with output impedance of the RF-power source 83. The RF-power supply 8 is explained through an embodiment where the RF-power supply 8 applies RF power to the showerhead 3 serving as the upper electrode, but the RF-power supply 8 is not limited to the above-described embodiment. The RF-power supply 8 may be configured to apply RF power to the stage 2 serving as a lower electrode.

The controller 9 is, for example, a computer, and includes a central processing unit (CPU), a random access memory (RAM), a read only memory (ROM), an auxiliary storage device, and the like. The CPU operates based on one or more programs stored in the ROM or auxiliary storage device, and controls operations of the substrate-processing apparatus 101. The controller 9 may be provided inside or outside the substrate-processing apparatus 101. When the controller 9 is provided outside the substrate-processing apparatus 101, the controller 9 can control the substrate-processing apparatus 101 by a communication system, such as a wired communication system, a wireless communication system, or the like.

### [Film Formation Process Using Substrate-Processing Apparatus]

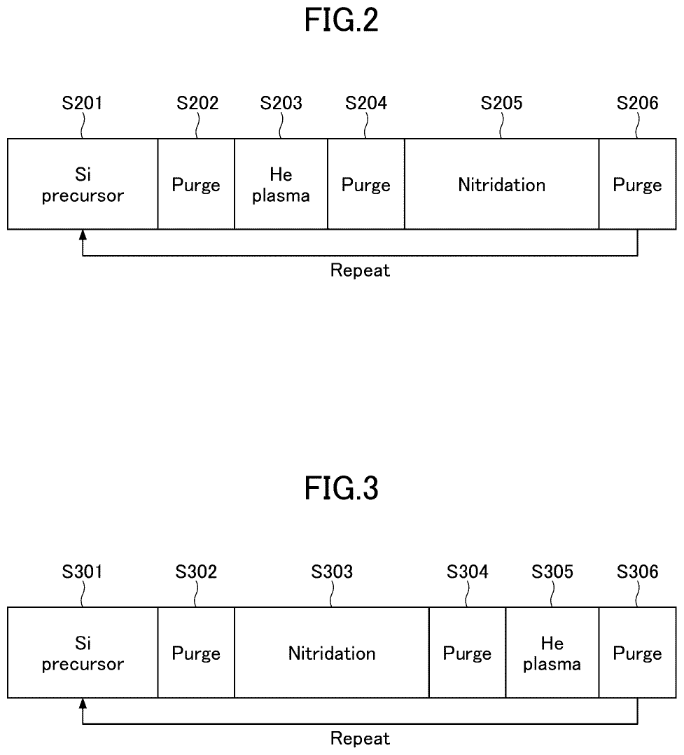

Examples of an SiN film formation process using the substrate-processing apparatus 101 will be described with reference to FIGS. 2 and 3.

FIG. 2 is a timing diagram illustrating one example of an SiN film forming process according to the first example. The substrate-processing apparatus 101 forms an SiN film on a substrate W, to which a base film has been formed, according to a PE-ALD process.

The PE-ALD process according to the first example illustrated in FIG. 2 is a process in which a cycle including a silicon-precursor-gas supplying step (step of i)) S201, a purging step S202, an adsorption-inhibition-region formation step (step of iii)) S203, a purging step S204, a nitridation step (step of ii)) S205, and a purging step S206 is repeated a set number of times to form an SiN film having a desired thickness on the substrate W. Only one cycle is illustrated in FIG. 2.

The silicon-precursor-gas supplying step S201 is a step of supplying a silicon precursor gas (DCS gas) into a processing space 38. In the silicon-precursor-gas supplying step S201, first, an Ar gas is supplied from the Ar gas sources 53a and 54a through the gas supply lines 53b and 54b, respectively, in the state in which the valves 53e and 54e are opened. In addition, a silicon precursor gas is supplied from the silicon precursor gas source 51a into the processing space 38 in the processing chamber 1 through the gas supply line 51b by opening the valve 51e. During the supply of the silicon precursor gas, the silicon precursor gas is temporarily retained in the reservoir tank 51d, followed by being supplied to the processing chamber 1. Thus, the silicon precursor is adsorbed on a surface of the substrate W to form an adsorption layer of the silicon precursor on the surface of the substrate W. Specifically, adsorption sites to which molecules of the silicon precursor are adsorbed are formed at the surface of the substrate W. Since the molecules of the silicon precursor are adsorbed to the adsorption sites, the adsorption layer of the silicon precursor is formed on the surface of the substrate W.

The purging step S202 is a step of purging the excess silicon precursor and the like from the processing space 38. In the purging step S202, the valve 51e is closed to stop the supply of the silicon precursor gas, in the state in which the supply of the Ar gas through the gas supply lines 53b and 54b is continued. Thus, the Ar gas is supplied from the Ar gas sources 53a and 54a into the processing space 38 in the processing chamber 1 through the gas supply lines 53b and 54b. By supplying the Ar gas in the above manner, the excess silicon precursor gas and the like are purged from the processing space 38. In addition, the reservoir tank 51d is filled with the silicon precursor gas by closing the valve 51e.

The adsorption-inhibition-region formation step S203 is a step of supplying an adsorption inhibition gas (He gas) into the processing space 38 and causing plasma excitation of the adsorption inhibition gas. In the adsorption-inhibition-region formation step S203, the valve 55e is opened in the state in which the supply of the Ar gas (first inert gas) through the gas supply lines 53b and 54b is continued. Thus, the adsorption inhibition gas is supplied from the adsorption inhibition gas source 55a into the processing space 38 through the gas supply line 55b. In addition, RF is applied to the upper electrode by the RF-power source 83 in the state in which the supply of the Ar gas through gas supply lines 53b and 54b and the supply of the adsorption inhibition gas through the gas supply line 55b are continued, thereby generating plasma in the processing space 38. Thus, the surface of the substrate W is exposed to He plasma. Since the surface of the substrate W is exposed to He plasma, an adsorption inhibition region, which is a region where the number of adsorption sites for the silicon precursor is reduced, is formed.

One example of the preferred ranges of the He plasma conditions in step S203 is presented below.
Duration of step S203: 0.1 seconds to 10.0 seconds
RF power of step S203: 30 W to 3,000 W
Pressure of step S203: 0.1 Torr to 50 Torr

The purging step S204 is a step of purging the He gas and the like from the processing space 38. In the purging step S204, the valve 55e is closed to stop the supply of the He gas in the state in which the supply of the Ar gas through the gas supply lines 53b and 54b is continued. In addition, the application of RF to the upper electrode by the RF-power source 83 is stopped. Thus, the Ar gas is supplied from the Ar gas sources 53a and 54a into the processing space 38 in the processing chamber 1 through the gas supply lines 53b and 54b. By supplying the Ar gas in the above manner, the He gas and the like are purged from the processing space 38.

The nitridation step S205 is a step of supplying a reaction gas (NH₃ gas), thereby nitriding the adsorption layer of the silicon precursor formed on the surface of the substrate W. In addition, the nitridation step S205 is a step of causing plasma excitation of the NH₃ gas supplied as the reaction gas. In the nitridation step S205, the valve 52e is opened in the state in which the supply of the Ar gas through the gas supply lines 53b and 54b is continued. Thus, the reaction gas is supplied from the reaction gas source 52a into the processing space 38 through the gas supply line 52b. In addition, RF is applied to the upper electrode by the RF-power source 83 in the state in which the supply of the Ar gas through the gas supply lines 53b and 54b and the supply of the reaction gas through the gas supply line 52b are continued, thereby generating plasma in the processing space 38. Thus, the nitriding of the adsorption layer of the silicon precursor on the surface of the substrate W is caused, thereby forming an SiN film. Moreover, adsorption sites to which molecules of the silicon precursor are adsorbed are formed at the surface of the substrate W. The adsorption sites are, for example, NHx groups.

The purging step S206 is a step of purging the excess reaction gas and the like from the processing space 38. In the purging step S206, the valve 52e is closed to stop the supply of the reaction gas in the state in which the supply of the Ar gas through the gas supply lines 53b and 54b is continued. In addition, the application of RF to the upper electrode by the RF-power source 83 is stopped. Thus, the Ar gas is supplied from the Ar gas sources 53a and 54a into the processing space 38 in the processing chamber 1 through the gas supply lines 53b and 54b. By supplying the Ar gas in the above manner, the excess reaction gas and the like are purged from the processing space 38.

By repeating the cycle of the above steps, an SiN film is formed on the substrate W.

The purging step S202 for the silicon precursor gas may be omitted, and the adsorption-inhibition-region formation step S203 may be performed after the silicon-precursor-gas supplying step S201.

Although the nitridation step S205 is described as the reaction of the plasma active species, the nitridation step S205 is not limited to the reaction of the plasma active species, and may be performed by a thermal reaction. In the case of the thermal reaction, the substrate W placed on the stage 2 is heated at a desired processing temperature by a heater 21.

FIG. 3 is a timing diagram illustrating one example of an SiN film formation process according to the second example. The substrate-processing apparatus 101 forms an SiN film on a substrate W, to which a base film has been formed, according to the PE-ALD process.

The PE-ALD process of the second example illustrated in FIG. 3 is a process in which a cycle including a silicon-precursor-gas supplying step (step of i)) S301, a purging step S302, a nitridation step (step of ii)) S303, a purging step S304, an adsorption-inhibition-region formation step (step of iii)) S305, and a purging step S306 is repeated a set number of times to form an SiN film having a desired thickness on the substrate W. Only one cycle is illustrated in FIG. 3.

The silicon-precursor-gas supplying step S301 is a step of supplying a silicon precursor gas (DCS gas) into a processing space 38. In the silicon-precursor-gas supplying step S301, first, an Ar gas is supplied from the Ar gas sources 53a and 54a through the gas supply lines 53b and 54b, respectively, in the state in which the valves 53e and 54e are opened. In addition, a silicon precursor gas is supplied from the silicon precursor gas source 51a into the processing space 38 in the processing chamber 1 through the gas supply line 51b by opening the valve 51e. During the supply of the silicon precursor gas, the silicon precursor gas is temporarily retained in the reservoir tank 51d, followed by being supplied to the processing chamber 1. Thus, the silicon precursor is adsorbed onto a surface of the substrate W to form an adsorption layer of the silicon precursor on the surface of the substrate W. Specifically, adsorption sites to which molecules of the silicon precursor are adsorbed are formed at the surface of the substrate W. Since the molecules of the silicon precursor are adsorbed to the adsorption sites, the adsorption layer of the silicon precursor is formed on the surface of the substrate W.

The purging step S302 is a step of purging the excess silicon precursor gas or the like from the processing space 38. In the purging step S302, the valve 51e is closed to stop the supply of the silicon precursor gas, in the state in which the supply of the Ar gas through the gas supply lines 53b and 54b is continued. Thus, the Ar gas is supplied from the Ar gas sources 53a and 54a into the processing space 38 in the processing chamber 1 through the gas supply lines 53b and 54b. By supplying the Ar gas in the above manner, the excess silicon precursor gas and the like are purged from the processing space 38. In addition, the reservoir tank 51d is filled with the silicon precursor gas by closing the valve 51e.

The nitridation step S303 is a step of supplying a reaction gas (NH₃ gas), thereby nitriding the adsorption layer of the silicon precursor formed on the surface of the substrate W. In addition, the nitridation step S303 is a step of causing plasma excitation of the NH₃ gas supplied as the reaction gas. In the nitridation step S303, the valve 52e is opened in the state in which the supply of the Ar gas through the gas supply lines 53b and 54b is continued. Thus, the reaction gas is supplied from the reaction gas source 52a into the processing space 38 through the gas supply line 52b. In addition, RF is applied to the upper electrode by the RF-power source 83 in the state in which the supply of the Ar gas through the gas supply lines 53b and 54b and the supply of the reaction gas through the gas supply line 52b are continued, thereby generating plasma in the processing space 38. Thus, the nitriding of the adsorption layer of the silicon precursor on the surface of the substrate W is caused, thereby forming an SiN film. Moreover, adsorption sites to which molecules of the silicon precursor are adsorbed are formed at the surface of the substrate W. The adsorption sites are, for example, NHx groups.

The purging step S304 is a step of purging the excess reaction gas and the like from the processing space 38. In the purging step S304, the valve 52e is closed to stop the supply of the reaction gas in the state in which the supply of the Ar gas through the gas supply lines 53b and 54b is continued. In addition, the application of RF to the upper electrode by the RF-power source 83 is stopped. Thus, the Ar gas is supplied from the Ar gas sources 53a and 54a into the processing space 38 in the processing chamber 1 through the gas supply lines 53b and 54b. By supplying the Ar gas in the above manner, the excess reaction gas and the like are purged from the processing space 38.

The adsorption-inhibition-region formation step S305 is a step of supplying an adsorption inhibition gas (He gas) into the processing space 38 and causing plasma excitation of the adsorption inhibition gas. In the adsorption-inhibition-region formation step S305, the valve 55e is opened in the state in which the supply of the Ar gas through the gas supply lines 53b and 54b is continued. Thus, the adsorption inhibition gas is supplied from the adsorption inhibition gas source 55a into the processing space 38 through the gas supply line 55b. In addition, RF is applied to the upper electrode by the RF-power source 83 in the state in which the supply of the Ar gas through gas supply lines 53b and 54b and the supply of the adsorption inhibition gas through the gas supply line 55b are continued, thereby generating plasma in the processing space 38. Thus, the surface of the substrate W is exposed to He plasma. Since the surface of the substrate W is exposed to He plasma, an adsorption inhibition region, which is a region where the number of adsorption sites for the silicon precursor is reduced, is formed.

One example of the preferred ranges of the He plasma conditions in step S305 is presented below.
Duration of step S305: 0.1 seconds to 10.0 seconds
RF power of step S305: 30 W to 3,000 W
Pressure of step S305: 0.1 Torr to 50 Torr

The purging step S306 is a step of purging the He gas and the like from the processing space 38. In the purging step S306, the valve 55e is closed to stop the supply of the He gas in the state in which the supply of the Ar gas through the gas supply lines 53b and 54b is continued. In addition, the application of RF to the upper electrode by the RF-power source 83 is stopped. Thus, the Ar gas is supplied from the Ar gas sources 53a and 54a into the processing space 38 in the processing chamber 1 through the gas supply lines 53b and 54b. By supplying the Ar gas in the above manner, the He gas and the like are purged from the processing space 38.

By repeating the cycle of the above steps, an SiN film is formed on the substrate W.

The purging step S304 for the reaction gas may be omitted, and the adsorption-inhibition-region formation step S305 may be performed after the nitridation step S303.

Although the nitridation step S303 is described as the reaction of the plasma active species, the nitridation step S303 is not limited to the reaction of the plasma active species, and may be performed by a thermal reaction. In the case of the thermal reaction, the substrate W placed on the stage 2 is heated at a desired processing temperature by a heater 21.

Here, one example of an SiN film formation process according to a referential example will be described. The PE-ALD process according to the referential example is a process, in which a cycle of a silicon-precursor-gas supplying step, a purging step, a nitridation step, and a purging step is repeated a set number of times so that a silicon precursor gas and a reaction gas are alternately supplied to form an SiN film of a desired thickness on a substrate W. Specifically, the SiN film formation process according to the referential example is different from the SiN film formation process according to the first example (see FIG. 2) and the SiN film formation process according to the second example (see FIG. 3) in that the SiN film formation process according to the referential example does not include an adsorption-inhibition-region formation step (S203 or S305) and a He gas purging step (S204 or S306). The other steps are the same and therefore redundant description is omitted.

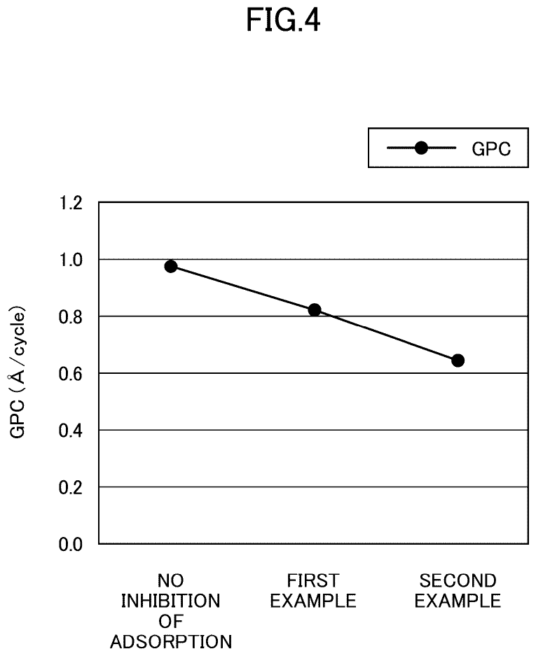

FIG. 4 is one example of a graph illustrating a film formation speed. The vertical axis represents the film formation speed (growth per cycle (GPC)).

“First example” at the center represents the result of the film formation speed when formation of an SiN film is performed according to the process illustrated in FIG. 2. “Second example” on the right represents the result of the film formation speed when formation of an SiN film is performed according to the process illustrated in FIG. 3. “No adsorption inhibition” represents the result of the film formation speed when formation of an SiN film is performed according to the PE-ALD process without performing the adsorption-inhibition-region formation step (S203 or S305) and the He gas purging step (S204 or S306). Specifically, the PE-ALD process of “no adsorption inhibition” is a process in which a cycle of a silicon-precursor-gas supplying step, a purging step, a nitridation step, and a purging step is repeated a set number of times so that a silicon precursor gas and a reaction gas are alternately supplied to form an SiN film having a desired film on a substrate W.

As presented in FIG. 4, the film formation speed is reduced in the “first example” and “second example” compared with the “no adsorption inhibition.” Namely, the results demonstrate that an effect of inhibiting adsorption on the substrate W is achieved by He plasma.

FIG. 5 is one example of a graph illustrating a relation between a plasma exposure time and NHx groups in the film. Here, an SiN film is formed by the PE-ALD process according to the first example (see FIG. 2), except that the time during which the substrate W is exposed to He plasma (i.e., duration of the adsorption-inhibition-region formation step S203) is varied, and the NHx group (N—H bond, x=1 or 2) is measured by Fourier transform infrared spectroscopy (FT-IR). The horizontal axis represents the time during which the substrate W is exposed to He plasma. The vertical axis represents emission intensity at the wavelength corresponding to the NHx group measured by Fourier transform infrared spectroscopy (FT-IR).

As presented in FIG. 5, it is demonstrated that the number of NHx groups (N—H bonds) in the film is reduced by exposing the substrate W to He plasma. Moreover, the bond of N is replaced with an Si—N bond. Examples of the NHx groups include NH groups and NH₂ groups.

The silicon precursor is adsorbed by substituting H of the NHx groups in the film with Si of the silicon precursor. Specifically, the NHx groups function as adsorption sites to which the silicon precursor is adsorbed at the surface of the substrate W. Since the number of the NHx groups is reduced, an amount of the silicon precursor adsorbed on the surface of the substrate W is reduced.

As described above, the longer the time during which the substrate W is exposed to He plasma is, the smaller the number of NHx groups serving as adsorption sites in the film is, which indicates that an effect of inhibiting adsorption of the silicon precursor is improved.

FIGS. 6A to 6C illustrate one example of schematic cross-sectional views illustrating a process of filling a recess 601 with an SiN film. The substrate W includes a film 600. The recess 601, such as a trench, a hole, or the like, is formed in the film 600.

As illustrated in FIG. 6A, in the adsorption-inhibition-region formation step (S203 or S305), the substrate W is exposed to He plasma, thereby forming an adsorption inhibition region 620, in which the number of adsorption sites is reduced, on an upper surface of the film 600 and upper portions of side surfaces of the recess 601.

Thus, by repeating the PE-ALD cycle illustrated n FIG. 2 or 3, GPC of the lower portions of the side surfaces of the recess 601 becomes relatively high so that an SiN film 610 having a V-shaped cross-sectional shape is formed, as illustrated in FIG. 6B.

According to the increase in the number of the ALD cycles repeated, the conditions for generating He plasma are changed in stages. Specifically, at least one selected from the group consisting of the power (RF power) of He plasma, a supply amount of a helium (He) gas, partial pressure of the He gas (partial pressure and concentration of the He gas in the gas mixture of the He gas and the Ar gas), internal pressure of the processing chamber, and irradiation time (exposure time) with the He plasma is changed (increased or decreased) in a stepwise manner.

That is, if the number of the ALD cycles increases and the filling of the SiN film 610 from the bottom surface of the recess 601 progresses, the aspect ratio of the recess 601 changes. Therefore, a range where the adsorption inhibition region 620 is formed is changed by changing the conditions for generating He plasma.

When the number of the ALD cycles reaches a set number, the conditions for generating He plasma are changed so that a range of the adsorption inhibition region 620 formed on the side surfaces of the recess 601 extends to only the shallower portions of the recess 601. Thus, as illustrated in FIG. 6B, the adsorption inhibition region 620, in which the number of the adsorption sites is reduced, is formed on the top surface of the film 600 and along the periphery of the opening of the recess 601.

Specifically, the change made in the conditions for generating He plasma may be a decrease in power (RF power) of the He plasma. Alternatively, the supply amount of the He gas may be reduced. Moreover, the partial pressure (concentration) of the He gas may be reduced. Furthermore, the internal pressure of the processing chamber may be reduced. Also, the irradiation time (exposure time) with the He plasma may be shortened. Two or more of the preceding changes may be performed in combination.

Thereafter, the conditions for generating He plasma may be changed in stages every time the number of the ALD cycles reaches a set number.

Thus, the recess 601 is filled with the SiN film 610 without any void, as illustrated in FIG. 6C.

Further, by using a He gas, which is a non-corrosive gas, as the adsorption inhibition gas, corrosion of the apparatus can be inhibited.

It has been described that the adsorption-inhibition-region formation step (step of iii)) is performed after the silicon-precursor-gas supplying step (step of i)) S201 (and before the nitridation step (step of ii)) S205) in the example illustrated in FIG. 2, and is performed after the nitridation step (step of ii)) S303 (and before the silicon-precursor-gas supplying step (step of i)) S301) in the example illustrated in FIG. 3, but the timing of the adsorption-inhibition-region formation step (step of iii)) is not limited to the above examples.

The adsorption-inhibition-region formation step (step of iii)) may be performed both after the silicon-precursor-gas supplying step (step of i)) and after the nitridation step (step of ii)).

Moreover, the ALD cycle for forming an SiN film may include an adsorption-inhibition-region formation step (step of iv)) using a N₂ gas (nitrogen gas; second adsorption inhibition gas). The adsorption-inhibition-region formation step (step of iv)) using the N₂ gas may be performed before the silicon-precursor-gas supplying step (step of i)) S201 or S301.

The adsorption-inhibition-region formation step using the N₂ gas is a step of supplying a N₂ gas into the processing space 38, and causing plasma excitation of the N₂ gas. In the adsorption-inhibition-region formation step using the N₂ gas, a valve (not illustrated) provided to a No gas supply line of a N₂ gas source (not illustrated) is opened in the state in which the supply of the Ar gas (second inert gas) through the gas supply lines 53b and 54b is continued. Thus, the No gas is supplied from the N₂ gas source into the processing space 38 through the gas supply line. In addition, RF is applied to the upper electrode by the power source 83 in the state in which the supply of the Ar gas through the gas supply lines 53b and 54b and the supply of the N₂ gas through the N₂ gas supply line are continued, thereby generating plasma in the processing space 38. Thus, the surface of the substrate W is exposed to nitrogen plasma.

According to the increase in the number of the ALD cycles repeated, the conditions for generating nitrogen plasma may be changed in stages. Specifically, at least one selected from the group consisting of the power (RF power) of nitrogen plasma, a supply amount of a nitrogen gas, partial pressure of the nitrogen gas (partial pressure and concentration of the nitrogen gas in the gas mixture of the nitrogen gas and the Ar gas), internal pressure of the processing chamber, and irradiation time (exposure time) with the nitrogen plasma may be changed (increased or decreased) in a stepwise manner.

Moreover, the ALD cycle for forming an SiN film may include an adsorption-inhibition-region formation step (step of v)) using a halogen-containing gas (third adsorption inhibition gas). The adsorption-inhibition-region formation step (step of v)) using the halogen-containing gas may be performed before the silicon-precursor-gas supplying step (step of i)) S201 or S301.

As the halogen-containing gas, a halogen gas (e.g., a chlorine (Cl₂) gas), a halogen compound gas, or any combination of the preceding gasses may be used. The adsorption-inhibition-region formation step using the halogen-containing gas is a step of supplying a halogen-containing gas into the processing space 38, and causing plasma excitation of the halogen-containing gas. In the adsorption-inhibition-region formation step using the halogen-containing gas, a valve (not illustrated) provided to a halogen-containing gas supply line of a halogen-containing gas source (not illustrated) is opened in the state in which the supply of the Ar gas (third inert gas) through the gas supply lines 53b and 54b is continued. Thus, the halogen-containing gas is supplied from the halogen-containing gas source into the processing space 38 through the gas supply line. In addition, RF is applied to the upper electrode from the RF-power source 83 in the state in which the supply of the Ar gas through the gas supply lines 53b and 54b, and the supply of the halogen-containing gas through the halogen-containing gas supply line are continued, thereby generating plasma in the processing space 38. Thus, the surface of the substrate W is exposed to plasma of the halogen-containing gas. Note that the halogen-containing gas (e.g., a halogen gas and a halogen compound gas) is not limited to the Cl₂ gas. The halogen-containing gas may be, for example, a hydrogen fluoride (HF) gas, a hydrogen chloride (HCl) gas, a hydrogen bromide (HBr) gas, or the like.

According to the increase in the number of the ALD cycles repeated, the conditions for generating plasma of the halogen-containing gas may be changed in stages. Specifically, at least one selected from the group consisting of the power (RF power) of plasma of the halogen-containing gas, a supply amount of the halogen-containing gas, partial pressure of the halogen-containing gas (partial pressure and concentration of the halogen-containing gas in the gas mixture of the halogen-containing gas and the Ar gas), internal pressure of the processing chamber, and irradiation time (exposure time) with plasma of the halogen-containing gas may be changed (increased or decreased) in a stepwise manner.

Further, the ALD cycle for forming an SiN film may include both the adsorption-inhibition-region formation step (step of iv)) using the N₂ gas and the adsorption-inhibition-region formation step (step of v)) using the halogen-containing gas. In this case, the adsorption-inhibition-region formation step (step of iv)) using the N-gas and the adsorption-inhibition-region formation step (step of v)) using the halogen-containing gas may be performed before the silicon-precursor-gas supplying step (step of i)) S201 or S301.

According to an increase in the number of the ALD cycles repeated, the adsorption-inhibition-region formation step may be switched between the adsorption-inhibition-region formation step (step of iii)) using the He gas, and the adsorption-inhibition-region formation step (step of iv)) using the N₂ gas, the adsorption-inhibition-region formation step (step of v)) using the halogen-containing gas. Thus, the recess 601 is efficiently filled with an SiN film 610 by switching the adsorption inhibition region.

Although the ALD cycle has been explained through the example in which the adsorption-inhibition-region formation step (step of iv)) using the N₂ gas (second adsorption inhibition gas), the adsorption-inhibition-region formation step (step of v)) using the halogen-containing gas (third adsorption inhibition gas), or both are performed at a different timing from the timing of the adsorption-inhibition-region formation step (step of iii)) S203 or S305 using the He gas (first adsorption inhibition gas). However, the timings are not limited to the above example. The adsorption-inhibition-region formation step (step of iii)) S203 or S305 may be a step of supplying, as adsorption inhibition gasses, a nitrogen gas (second adsorption inhibition gas), a halogen-containing gas (third adsorption inhibition gas), or both into the processing space 38, in addition to the He gas (first adsorption inhibition gas), and causing plasma excitation of the adsorption inhibition gases. Thus, the surface of the substrate W is exposed to nitrogen plasma, plasma of the halogen-containing gas, or both, in addition to helium plasma, thereby forming an adsorption inhibition region on the substrate W.

According to one aspect of the present disclosure, as described above, a substrate-processing method and a substrate-processing apparatus, which fill a recess formed in a substrate with an SiN film, can be provided.

While the embodiments of the film formation process of the present embodiment using the substrate-processing apparatus 101 have been described above, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosure.

What is claimed is:

1. A substrate-processing method of filling a recess formed in a surface of a substrate with a silicon nitride film, the substrate-processing method comprising:
a) repeating a cycle including:
i) supplying a silicon precursor gas to form an adsorption layer on the substrate,
ii) supplying a nitrogen-containing gas to cause nitriding of the adsorption layer, and
iii) supplying a helium-containing gas and generating helium plasma in a processing chamber to expose the substrate to the helium plasma, thereby forming an adsorption inhibition region on the substrate; and
b) changing conditions for generating the helium plasma according to an increase in a number of the cycles repeated.

2. The substrate-processing method according to claim 1,
wherein b) further comprises stepwise increasing or decreasing at least one selected from a group consisting of power for generating the helium plasma, a supply amount of the helium-containing gas, partial pressure of the helium-containing gas, internal pressure of the processing chamber, and an exposure time with the helium plasma.

3. The substrate-processing method according to claim 2,
wherein the adsorption inhibition region is a region in which a number of adsorption sites for a silicon precursor of the silicon precursor gas is reduced.

4. The substrate-processing method according to claim 3,
wherein iii) further comprises supplying the helium-containing gas and a first inert gas.

5. The substrate-processing method according to claim 4,
wherein the first inert gas is an argon gas.

6. The substrate-processing method according to claim 5,
wherein iii) is performed after i).

7. The substrate-processing method according to claim 5,
wherein iii) is performed after ii).

8. The substrate-processing method according to claim 5,
wherein iii) is performed after i) and after ii).

9. The substrate-processing method according to claim 1,
wherein iii) further comprises supplying
the helium-containing gas, and
a nitrogen gas, a halogen-containing gas, or both the nitrogen gas and the halogen-containing gas.

10. The substrate-processing method according to claim 1,
wherein the cycle further comprises:
iv) supplying a nitrogen gas to the processing chamber, and generating nitrogen plasma to expose the substrate to the nitrogen plasma.

11. The substrate-processing method according to claim 10,
wherein at least one selected from a group consisting of power for generating the nitrogen plasma, a supply amount of the nitrogen gas, partial pressure of the nitrogen gas, internal pressure of the processing chamber, and an exposure time with the nitrogen plasma is increased or decreased stepwise according to an increase in a number of the cycles repeated.

12. The substrate-processing method according to claim 11,
wherein iv) further comprises supplying the nitrogen gas and a second inert gas.

13. The substrate-processing method according to claim 12,
wherein the second inert gas is an argon gas.

14. The substrate-processing method according to claim 1,
wherein the cycle further comprises:
v) supplying a halogen-containing gas to the processing chamber, and generating plasma of the halogen-containing gas to expose the substrate to the plasma of the halogen-containing gas.

15. The substrate-processing method according to claim 14,
wherein the halogen-containing gas is at least one selected from a group consisting of a Cl₂ gas, a HF gas, a HCl gas, and a HBr gas.

16. The substrate-processing method according to claim 14,
wherein at least one selected from a group consisting of power for generating the plasma of the halogen-containing gas, a supply amount of the halogen-containing gas, partial pressure of the halogen-containing gas, internal pressure of the processing chamber, and an exposure time with the plasma of the halogen-containing gas is increased or decreased stepwise according to an increase in a number of the cycles repeated.

17. The substrate-processing method according to claim 1,
wherein the cycle further includes:
iv) supplying a nitrogen gas to the processing chamber, and generating nitrogen plasma to expose the substrate to the nitrogen plasma; and
v) supplying a halogen-containing gas to the processing chamber, and generating plasma of the halogen-containing gas to expose the substrate to the plasma of the halogen-containing gas.

18. The substrate-processing method according to claim 1,
wherein the silicon precursor is at least one selected from a group consisting of halogenated silane, aminosilane, and silyl amine.

19. The substrate-processing method according to claim 1,
wherein the nitrogen-containing gas includes at least one selected from a group consisting of an NH₃ gas, an N₂H₂ gas, an N₂ gas, a gas mixture of an N₂ gas and a H₂ gas, any combination of the preceding gasses, and a plasma active species of any of the preceding gasses.

20. A substrate-processing apparatus comprising:
a processing chamber including a stage on which a substrate is placed;
a gas source configured to supply a gas to the processing chamber;
a high-frequency power supply configured to apply high-frequency power, thereby generating plasma in the processing chamber;
a memory; and
a processor coupled to the memory and configured to perform a process including:
a) repeating a cycle including:
i) supplying a silicon precursor gas to form an adsorption layer on the substrate;
ii) supplying a nitrogen-containing gas to cause nitriding of the adsorption layer; and
iii) supplying a helium-containing gas and generating helium plasma in a processing chamber to expose the substrate to the helium plasma, thereby forming an adsorption inhibition region on the substrate,
thereby, forming a silicon nitride film on the substrate; and
b) changing conditions for generating the helium plasma according to an increase in a number of the cycles repeated.
